(19) United States
(12) Patent Application Publication
(10) Pub. No.: US 2025/0287813 A1
(43) Pub. Date: Sep. 11, 2025

(54) DISPLAY PANEL, METHOD FOR MANUFACTURING DISPLAY PANEL, AND DISPLAY DEVICE

(71) Applicants: Hefei Xinsheng Optoelectronics Technology Co., Ltd., Hefei, Anhui (CN); BOE Technology Group Co., Ltd., Beijing (CN)

(72) Inventors: Haitao WANG, Beijing (CN); Ning LIU, Beijing (CN); Can YUAN, Beijing (CN); Jun CHENG, Beijing (CN); Ce ZHAO, Beijing (CN); Cheng XU, Beijing (CN); Dandan ZHOU, Beijing (CN)

(21) Appl. No.: 18/861,843

(22) PCT Filed: Feb. 7, 2024
(86) PCT No.: PCT/CN2024/076557

§ 371 Date: Oct. 30, 2024

(30) Foreign Application Priority Data
Mar. 20, 2023 (CN) 202310284020.5

(51) Int. Cl. H10K 59/80; H10K 59/123; H10K 102/00; H10K 102/10

(52) U.S. Cl. CPC H10K 59/80522; H10K 59/123; H10K 59/80516; H10K 2102/103; H10K 2102/351

(57) ABSTRACT

A display panel includes a drive backplane, a first electrode layer, a light-emitting layer, a second electrode layer and a plurality of auxiliary electrode structures, the first electrode layer and the plurality of auxiliary electrode structures are disposed on the drive backplane. The first electrode layer includes the plurality of first electrode structures, the first electrode structures include a first conductive layer, a metal layer and a second conductive layer that are sequentially stacked on the drive backplane in a direction away from the drive backplane, the auxiliary electrode structures include a first conductive layer, a metal layer and a second conductive layer that are sequentially stacked on the drive backplane in a direction away from drive backplane. A thickness of the metal layer of the first electrode structure is less than a thickness of the metal layer of the auxiliary electrode structure.

### CROSS-REFERENCE TO RELATED APPLICATIONS

This application is a national stage of International Application No. PCT/CN2024/076557, filed on Feb. 7, 2024, which claims the benefit of priority to Chinese Patent Application No. 202310284020.5 filed on Mar. 20, 2023, and entitled “DISPLAY PANEL, METHOD FOR MANUFACTURING SAME, AND DISPLAY DEVICE,” both of which are incorporated by reference herein.

### TECHNICAL FIELD

Embodiments of the present disclosure relate to the field of display technologies, and in particular, relate to a display panel, a method for manufacturing the same, and a display device.

### BACKGROUND

Display devices are widely used in people's daily life, for example, such as in mobile phones, displays, or tablet computers. Display panels are important components of the display devices.

### SUMMARY

Embodiments of the present disclosure provide a display panel, a method for manufacturing the same, and a display device, which can reduce the particles size introduced during the formation of the first electrode layer by thinning the metal layer within the first electrode layer, and thereby reducing dark-dot type defects. The technical solutions are as follows:

According to some embodiments of the present disclosure, a display panel is provided. The display panel includes a drive backplane, a first electrode layer, a light-emitting layer, a second electrode layer, and a plurality of auxiliary electrode structures; wherein the first electrode layer and the auxiliary electrode structures are disposed on the drive backplane, and the first electrode layer includes a plurality of first electrode structures, wherein an orthographic projection of each of the first electrode structures on the drive backplane is not overlapped with an orthographic projection of each of the auxiliary electrode structures on the drive backplane; the light-emitting layer is disposed on a surface, away from the drive backplane, of the first electrode layer; the second electrode layer covers the light-emitting layer and the auxiliary electrode structures, the second electrode layer is connected to the auxiliary electrode structure; wherein, each of the first electrode structures include a first conductive layer, a metal layer and a second conductive layer that are sequentially stacked on the drive backplane in a direction away from the drive backplane, and each of the auxiliary electrode structures includes a first conductive layer, a metal layer and a second conductive layer that are sequentially stacked on the drive backplane in the direction away from the drive backplane; wherein a thickness of the metal layer of the first electrode structure is less than a thickness of the metal layer of the auxiliary electrode structure.

In some embodiments, the first conductive layer and the second conductive layer of the first electrode structure, and the first conductive layer and the second conductive layer of the auxiliary electrode structure are all made of a transparent material.

In some embodiments, the metal layer of the auxiliary electrode structure comprises a first sub-metal layer and a second sub-metal layer that are sequentially stacked in a direction away from the drive backplane, wherein a thickness of the second sub-metal layer is equal to the thickness of the metal layer of the first electrode layer, and the second sub-metal layer and the metal layer of the first electrode structure are made of a same material.

In some embodiments, the thickness of the metal layer of the first electrode structure is greater than or equal to 400 angstroms and less than or equal to 1500 angstroms.

In some embodiments, the first sub-metal layer is a monolayer structure.

In some embodiments, the metal layer of the first electrode structure and the second sub-metal layer are both multi-layer stacked structures.

In some embodiments, the first transparent conductive layer of the first electrode structure includes a first sub-layer and a second sub-layer that are sequentially stacked in the direction away from the drive backplane, wherein the first sub-layer is a crystallized indium tin oxide layer, and the second sub-layer is a buffer indium tin oxide layer.

In some embodiments, a hollow structure is arranged at a middle portion of the first sub-layer of the first electrode structure, wherein at least a portion of the second sub-layer of the first electrode structure is disposed within the hollow structure.

In some embodiments, the thickness of the first sub-layer of the first electrode structure is greater than or equal to the thickness of the second sub-layer of the first electrode structure, and the metal layer of the first electrode structure covers the hollow structure and is connected to at least a portion of the surface, away from the drive backplane, of the first sub-layer of the first electrode structure.

In some embodiments, the first transparent conductive layer of the auxiliary electrode structure includes a first sub-layer and a second sub-layer that are sequentially stacked in the direction away from the drive backplane, wherein the first sub-layer of the auxiliary electrode structure and the first sub-layer of the first electrode structure are disposed on a same layer and are made of a same material, and the second sub-layer of the auxiliary electrode structure and the second sub-layer of the first electrode structure are disposed on a same layer and are made of a same material.

In some embodiments, the display panel includes: a plurality of sub-pixels, wherein the plurality of sub-pixels are organized into a plurality of sub-pixel groups, and at least one sub-pixel of the sub-pixel groups includes the auxiliary electrode structure; wherein each of sub-pixel groups includes one sub-pixel or includes M rows and N columns of the sub-pixels, wherein M and N are both positive integers.

In some embodiments, the light-emitting layer includes a plurality of light-emitting structures, and the drive backplane includes a plurality of drive units; and the first sub-pixel of the sub-pixels includes one auxiliary electrode structure, two first electrode structures, two light-emitting structures, a portion of a second electrode layer, and a first drive unit, wherein the first drive unit is one of the drive units, and in the first sub-pixel, the first drive unit is electrically connected to the two first electrode structures.

In some embodiments, in the auxiliary electrode structures, along a direction parallel to the drive backplane, an edge, close to any of the first electrode structures, of the second conductive layer protrudes from an edge, close to the same first electrode structure, of the metal layer, such that a protrusion structure is formed. The protrusion structure interrupts the second electrode layer, and the interrupted portion of the second electrode layer is connected to the metal layer of the auxiliary electrode structure.

According to some embodiments of the present disclosure, a method for manufacturing a display panel is provided. The method includes: providing a drive backplane; forming a first electrode layer and a plurality of auxiliary electrode structures on the drive backplane, wherein the first electrode layer includes a plurality of first electrode structures, an orthographic projection of each of the first electrode structures on the drive backplane being not overlapped with an orthographic projection of each of the auxiliary electrode structures on the drive backplane; forming the light-emitting layer on a surface, away from the drive backplane, of the first electrode layer; and forming a second electrode layer on the surfaces of the light-emitting layer and the auxiliary electrode structures, wherein the second electrode layer is connected to the auxiliary electrode structures; wherein each of the first electrode structures includes a first transparent conductive layer, a metal layer, and a second transparent conductive layer that are sequentially stacked on the drive backplane in a direction away from the drive backplane; and each of the auxiliary electrode structures includes a first transparent conductive layer, a metal layer, and a second transparent conductive layer that are sequentially stacked on the drive backplane in the direction away from the drive backplane, wherein a thickness of the metal layer of the first electrode structures is less than a thickness of the metal layer of the auxiliary electrode structure.

According to some embodiments of the present disclosure, a display device is provided. The display device includes any one of the aforementioned display panels and a power supply circuit, wherein the power supply circuit is configured to supply power to the display panel.

### BRIEF DESCRIPTION OF DRAWINGS

For clearer descriptions of the technical solutions according to the embodiments of the present disclosure, the following briefly introduces the accompanying drawings to be required in the descriptions of the embodiments. Apparently, the accompanying drawings in the following description are merely some embodiments of the present disclosure, and persons of ordinary skills in the art may derive other accompanying drawings from these accompanying drawings without any creative effort.

FIG. 1 is a schematic cross-sectional view of a display panel according to some embodiments of the present disclosure;

FIG. 2 is a schematic diagram of a size of particles introduced into a metal layer within a first electrode structure in the related art;

FIG. 3 is a schematic diagram of a size of particles introduced after the metal layer within the first electrode structure is thinned according to some embodiments of the present disclosure;

FIG. 4 is a schematic cross-sectional view of another display panel according to some embodiments of the present disclosure;

FIG. 5 is a schematic cross-sectional view of a first electrode structure according to some embodiments of the present disclosure;

FIG. 6 is a schematic top view of a display panel according to some embodiments of the present disclosure;

FIG. 7 is a schematic diagram of distribution of auxiliary electrode structures according to some embodiments of the present disclosure;

FIG. 8 is another schematic diagram of distribution of auxiliary electrode structures according to some embodiments of the present disclosure;

FIG. 9 is a schematic top view of a sub-pixel including an auxiliary electrode structure according to some embodiments of the present disclosure;

FIG. 10 is a schematic cross-sectional view of another display panel according to some embodiments of the present disclosure;

FIG. 11 is a flowchart of a method for manufacturing a display panel according to some embodiments of the present disclosure.

### Reference Numerals and Denotations Thereof

1: drive backplane
10: drive unit
101: substrate
107: light shield layer;
108: buffer layer
102: active layer
103: gate insulation layer
104: gate layer
105: interlayer dielectric layer
106: source-drain layer
109: passivation layer
110: organic layer
2: first electrode layer
3: light-emitting layer
4: second electrode layer
40: portion of the second electrode layer
5: auxiliary electrode structure
6: pixel define layer
7: pixel
70: sub-pixel
700: sub-pixel group
71: first sub-pixel
72: second sub-pixel
73: third sub-pixel
21: first conductive layer of the first electrode structure
21a: first sub-layer of the first electrode structure
21b: second sub-layer of the first electrode structure
22: metal layer of the first electrode structure
23: second conductive layer of the first electrode structure
51: first conductive layer of the auxiliary electrode structure
51a: first sub-layer of the auxiliary electrode structure
51b: second sub-layer of the auxiliary electrode structure
52: metal layer of the auxiliary electrode structure
52a: first sub-metal layer
52b: second sub-metal layer
53: second conductive layer of the auxiliary electrode structure
531: protrusion structure

### DETAILED DESCRIPTION

In order to make the purpose, technical solutions and advantages of the present disclosure clearer, the embodiments of the application will be described in further detail below in conjunction with the accompanying drawings.

The terms used in the embodiments section of the present disclosure are used only for the purpose of interpreting embodiments of the present disclosure, and are not intended to limit the present disclosure. Unless otherwise defined, technical or scientific terms used in embodiments of the present disclosure should have the ordinary meaning understood by a person of ordinary skill in the field to which the present disclosure belongs. The terms “first,” “second,” “third,” and similar words used in the specification and the claims of the present patent application do not indicate any order, number, or importance, and are merely used to distinguish different components. Similarly, similar words such as “one,” “a/an,” or “the” do not indicate a quantitative limitation, but rather indicate the existence of at least one. Similar words such as “include” or “contain” mean that the elements or objects that appear before “include” or “contain,” includes or contain the elements or objects listed below and their equivalents, other elements or objects are not excluded.

In related arts, a display panel includes a drive backplane, a first electrode layer, and an auxiliary electrode structure. The first electrode layer and the auxiliary electrode structure are disposed on the drive backplane, and an orthographic projection of the first electrode layer on the drive backplane is not overlapped with an orthographic projection of the auxiliary electrode structure on the drive backplane. The first electrode layer includes a first transparent conductive layer, a metal layer, and a second transparent conductive layer that are sequentially stacked on the drive backplane. The auxiliary electrode structure includes a first transparent conductive layer, a metal layer and a second transparent conductive layer that are sequentially stacked on the drive backplane.

For a reliable connection between the auxiliary electrode structure and the second electrode layer, the metal layer of the auxiliary electrode structure is thicker. In order to streamline the manufacture process, the first electrode layer and the auxiliary electrode structure are usually layer fabricated in the same layer, and hence the metal layer of the first electrode layer is also thicker. When forming a thicker metal layer in the first electrode layer, relatively large and impurity particles may be introduced, which may pierce the light-emitting layer. As a result, a short circuit may be caused between the second electrode layer and the first electrode layer, resulting in dark-dot type defects and affecting the display effect.

Embodiments of the present disclosure provide a display panel. Exemplarily, the display panel may be an organic light-emitting diode (OLED) display panel or other type of display panel such as a micro light-emitting diode display panel. The differences between these display panel are mainly that the material of the light-emitting layer is different, and the structure of the pixel drive circuit is different. Description is given hereinafter using an OLED display panel as an example.

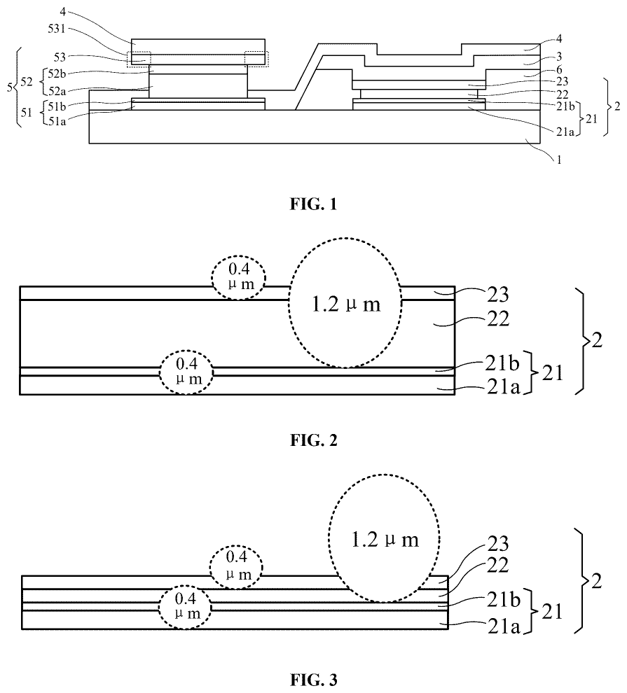

FIG. 1 is a schematic cross-sectional view of a display panel according to some embodiments of the present disclosure. As shown in FIG. 1, the display panel includes a drive backplane 1, a first electrode layer 2, a light-emitting layer 3, a second electrode layer 4, and an auxiliary electrode structure 5. The first electrode layer 2 and the auxiliary electrode structure 5 are disposed on the drive backplane 1. The first electrode layer includes a plurality of first electrode structures arranged in an array, an orthographic projection of each of the first electrode structures on the drive backplane 1 is not overlapped with an orthographic projection of the auxiliary electrode structure 5 on the drive backplane 1, that is, the first electrode structures and the auxiliary electrode structure 5 are arranged at intervals on the drive backplane 1. The light-emitting layer 3 is disposed on a surface, away from the drive backplane 1, of the first electrode layer 2. The second electrode layer 4 covers the light-emitting layer 3 and the auxiliary electrode structure 5, and the second electrode layer 4 is connected to the auxiliary electrode structure 5.

Each of the first electrode structures includes a first transparent conductive layer 21, a metal layer 22, and a second transparent conductive layer 23 that are sequentially stacked on the drive backplane 1 in a direction away from the drive backplane 1. The auxiliary electrode structure 5 includes a first transparent conductive layer 51, a metal layer 52, and a second transparent conductive layer 53 that are sequentially stacked on the drive backplane 1 in a direction away from the drive backplane 1. A thickness of the metal layer 22 of the first electrode structure is less than a thickness of the metal layer 52 of the auxiliary electrode structure 5.

In the related art, in order to simplify the process, and simultaneously produce the auxiliary electrode structure and the first electrode of the first electrode structure, the metal layer of the auxiliary electrode structure and the metal layer of the first electrode layer are set to the same thickness. However, in order to achieve the purpose of interrupting the second electrode layer from the auxiliary electrode structure, the metal layer of the auxiliary electrode structure requires a larger thickness. Therefore, during formation of the first electrode layer, because the thickness of the metal layer of the first electrode layer and the thickness of the metal layer of the auxiliary electrode structure are both thicker, and the magnitude of particles introduced during the formation of the metal layer is positively correlated with the thickness of the metal layer, particles of larger size and in larger quantities can be introduced at the time of forming the metal layer within the first electrode layer, which causes display defects. In the embodiments of the present disclosure, by making the thickness of the metal layer of the first electrode layer less than the thickness of the metal layer of the auxiliary electrode structure, that is, by reducing the thickness of the metal layer of the first electrode layer, the magnitude of the particles introduced during the production process of the first electrode layer may be reduced, thereby reducing the possibility of a short circuit between the first electrode layer and the second electrode layer caused by the particles piercing the light-emitting layer, and decreasing dark-dot type defects.

In the embodiments of the present disclosure, the auxiliary electrode structure 5 is connected to an electrode auxiliary line disposed on the source-drain layer inside the drive backplane 1. This configuration reduces the resistance of the entire second electrode layer 4, and decreases the voltage drop, facilitates application on large-size transparent products, and enhances voltage uniformity, such that the display effect is enhanced.

In some embodiments, the first conductive layer 21 and the second conductive layer 23 of the first electrode layer 2, and the first conductive layer 51 and the second conductive layer 53 of the auxiliary electrode structure 5 are all made of a transparent material.

In the embodiments of the present disclosure, the first electrode layer 2 may be an anode layer, and the second electrode layer 4 may be a cathode layer; alternatively, the first electrode layer 2 may be a cathode layer, and the second electrode layer 4 may be an anode layer.

In some embodiments, as shown in FIG. 1, the plurality of auxiliary electrode structures 5 interrupt the second electrode layer 4, and the interrupted portion of the second electrode layer 4 is connected to the metal layer 52 of the auxiliary electrode structure 5. As shown in FIG. 1, among the plurality of auxiliary electrode structures 5, an edge of the second conductive layer 53 near the first electrode structure along a direction parallel to the drive backplane 1 projects from an edge of the metal layer 52 near the same first electrode structure, such that a protrusion structure 531 is formed. The protrusion structure 531 interrupts the light-emitting layer 3, the second electrode layer 4 is connected to the metal layer 52 of the auxiliary electrode structure 5 at the interrupted portion. During the formation process of the second electrode layer 4, the protrusion structure 531 may naturally interrupt the second electrode layer 4, such that the second electrode layer 4 is connected to the metal layer 52 of the auxiliary electrode structure 5, thereby simplifying the preparation process.

In some embodiments, in the auxiliary electrode structures 5, at least one side edge of the second transparent conductive layer projects from the metal layer 52 of the auxiliary electrode structure 5 along a direction parallel to the drive backplane 1, such that the protrusion structure 531 is formed. As long as the second electrode layer 4 may be interrupted, the second electrode layer 4 may be connected to the metal layer 52 of the auxiliary electrode structure 5.

In some embodiments, the thickness of the metal layer 52 of the auxiliary electrode structure 5 is relatively large, ranging from 6000 angstroms to 7000 angstroms, for example, about 6500 angstroms. In this way, in the case that the auxiliary electrode structure 5 interrupts the second electrode layer 4, the interrupted portion of the second electrode layer 4 is connected to the metal layer 52 of the auxiliary electrode structure 5, enhancing the reliability of the connection between the auxiliary electrode structure 5 and the second electrode layer 4.

In the embodiments of the present disclosure, the thickness of the metal layer 22 of the first electrode structure is not less than 400 angstroms and not greater than 1500 angstroms, and much less than 6500 angstroms.

In the embodiments of the present disclosure, the metal layer 52 of the plurality of auxiliary electrode structures 5 includes a first sub-metal layer 52a and a second sub-metal layer 52b that are sequentially stacked on a side, away from the drive backplane 1, of the first transparent conductive layer 51. A thickness of the second sub-metal layer 52b is equal to the thickness of the metal layer 22 of the first electrode layer 2, and the second sub-metal layer 52b and the metal layer 22 of the first electrode layer 2 are made of a same material. In this way, the second sub-metal layer 52b of the auxiliary electrode structure 5 and the metal layer 22 of the first electrode layer 2 may be simultaneously fabricated to save time, and at the same time, the thickness of the metal layer inside the first electrode layer is thinned to decrease dark-dot type defects.

In some embodiments, the first conductive layer 21 of the first electrode structure includes a first sub-layer 21a and a second sub-layer 21b that are sequentially stacked in a direction away from the drive backplane 1. The first conductive layer 51 of the auxiliary electrode structure 5 includes a first sub-layer 51a and a second sub-layer 51b that are sequentially stacked in a direction away from the drive backplane 1. The first sub-layer 21a of the first electrode layer 2 and the first sub-layer 51a of the auxiliary electrode structure 5 are crystallized indium tin oxide (ITO) layers, and the second sub-layer 21b of the first electrode structure and the second sub-layer 51b of the auxiliary electrode structure 5 are buffer ITO layers. The crystallized ITO layer refers to a crystalline state ITO layer with high light transmittance and high conductivity. The buffer ITO layer refers to an ITO-induced ITO layer that has been annealed or crystallized to enhance the conductivity of the ITO layer.

In one possible embodiment, a thickness of the first sub-layer 21a of the first electrode structure is 1200 angstroms to 1600 angstroms, for example, 1400 angstroms; and a thickness of the second sub-layer 21b of the first electrode structure is 500 angstroms to 900 angstroms, for example, 700 angstroms.

In some embodiments, the first conductive layer 21 of the first electrode layer 2 includes only a crystallized ITO layer.

In the embodiments of the present disclosure, the first sub-layer 51a of the auxiliary electrode structure 5 and the first sub-layer 21a of the first electrode layer 2 are made of a same material, and have an equal thickness. Therefore, the first sub-layer 51a of the auxiliary electrode structure 5 and the first sub-layer 21a of the first electrode layer 2 may be fabricated simultaneously. The second sub-layer 51b of the auxiliary electrode structure 5 and the second sub-layer 21b of the first electrode layer 2 are made of a same material, and have an equal thickness. Therefore, the second sub-layer 51b of the auxiliary electrode structure 5 and the second sub-layer 21b of the first electrode layer 2 may be fabricated simultaneously.

Optionally, the second conductive layer 53 of the auxiliary electrode structure 5 and the second conductive layer 23 of the first electrode layer 2 are made of a same material, and have an equal thickness. Therefore, the second conductive layer 53 of the auxiliary electrode structure 5 and the second conductive layer 23 of the first electrode layer 2 may be fabricated simultaneously.

FIG. 2 is a schematic diagram of the size of particles introduced into a metal layer within a first electrode structure in the related art. As shown in FIG. 2, the first electrode layer 2 includes a first sub-layer 21a, a second sub-layer 21b, a metal layer 22, and a second conductive layer 23 that are sequentially stacked. The thicknesses of the metal layer 22 of the first electrode layer 2 and the metal layer 52 of the auxiliary electrode structure 5 are the same, about 6500 angstroms. During formation of the first sub-layer 21a, the second sub-layer 21b and the metal layer 22 within the first electrode layer 2, particles of different quantities and sizes are introduced.

Due to the thicker thickness of the metal layer 22 of the first electrode structure, the size of the particles introduced during the formation of the metal layer 22 is relatively large, which can reach 1.2 micrometers; and the quantity of the introduced particles is relatively large. Most of the dark-dots on a display panel, such as 83% of the dark-dots, are caused by the particles introduced by forming the metal layer 22 of the first electrode structure. Due to the larger/greater thickness of the metal layer 22, the particles embedded in the metal layer 22 are not easily cleaned off. After the second conductive layer 23, light-emitting layer 3 and the second electrode layer 4 are subsequently formed, these particles may pierce the light-emitting layer 3, causing a short circuit between the first electrode layer 2 and the second electrode layer 4, and resulting in dark-dot defects.

FIG. 3 is a schematic diagram of the size of particles introduced after the metal layer within the first electrode structure is thinned according to some embodiments of the present disclosure. As shown in FIG. 3, the first electrode structure includes a first sub-layer 21a, a second sub-layer 21b, a metal layer 22, and a second conductive layer 23 that are sequentially stacked. After the metal layer 22 is thinned, the particles introduced during the formation of the metal layer 22 are relatively small in size and quantity, for example, about 10% of the total quantity of introduced particles. The thickness of the metal layer 22 is reduced, and thus the particles embedded in the metal layer 22 are easily cleaned off. Therefore, the dark-dot type defects can be decreased after the metal layer 22 of the first electrode layer 2 is thinned.

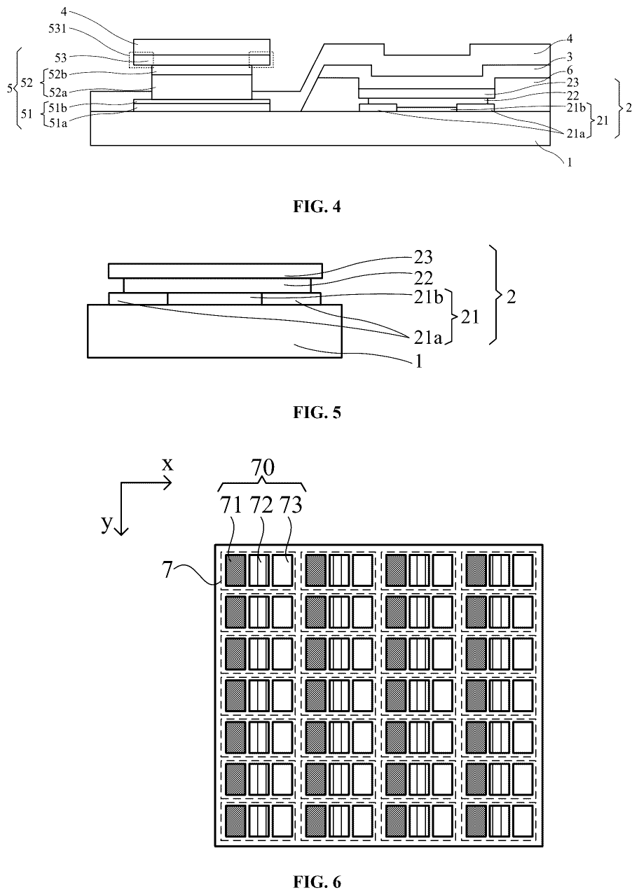

FIG. 4 is a schematic cross-sectional structure diagram of another display panel according to some embodiments of the present disclosure. The embodiment shown in FIG. 4 differs from the embodiment shown in FIG. 1 in that within the first electrode structure, a hollow structure is arranged at the middle portion of the first sub-layer 21a, wherein at least a portion of the second sub-layer 21b is disposed within the hollow structure. The thickness of the second sub-layer 21b is less than the thickness of the first sub-layer 21a. The metal layer 22 of the first electrode structure covers hollow structure and is connected to the second sub-layer 21b. This is because if only the metal layer of the first electrode structure is thinned, it is possible that a short circuit between the second electrode layer 4 and the first electrode layer 2 may occur as the particles introduced in the formation of the first sub-layer 21a may pierce the thinner metal layer 22, the second conductive layer 23, and light-emitting layer 3. Therefore, after the metal layer 22 is thinned, it is necessary to make a hollow structure in the first sub-layer 21a, and dispose the second sub-layer 21b in the hollow structure, so as to remove as much as possible the particles introduced by the formation of the first sub-layer 21a, thereby decreasing dark-dot type defects. The second sub-layer 21b is disposed between the metal layer 22 of the first electrode layer 2 and the drive backplane 1, serving as a buffer to prevent the metal layer 22 from directly connecting to the organic layer of the drive backplane and causing bulges and other defects at the connected portion.

FIG. 5 is a schematic cross-sectional view of a first electrode structure according to some embodiments of the present disclosure. In some other embodiments, as shown in FIG. 5, the thickness of the second sub-layer 21b is equal to the thickness of the first sub-layer 21a. At this time, the second sub-layer 21b of the first electrode layer 2 is flush with the first sub-layer 21a, and the metal layer of the first electrode layer 2 is simultaneously connected to the surfaces, away from the substrate, of the first sub-layer 21a and the second sub-layer 21b. Here, the second sub-layer 21b of the first electrode layer 2 is flush with the first sub-layer 21a, and “flush with” includes a situation of a small height difference between the first sub-layer 21a and the second sub-layer 21b, and the height difference is 5% of the thickness of the first sub-layer or the second sub-layer.

The distribution pattern of the auxiliary electrode structure 5 is described below in conjunction with FIG. 6 to FIG. 8.

FIG. 6 is a schematic top view of a display panel according to some embodiments of the present disclosure. As shown in FIG. 6, the display panel includes a plurality of pixels 7, wherein the plurality of pixels 7 are arranged in an array along the first direction x and the second direction y. Each of the pixels 7 includes a plurality of sub-pixels 70 arranged along the first direction x.

The plurality of sub-pixels 70 includes a first sub-pixel 71, a second sub-pixel 72, and a third sub-pixel 73 arranged along the first direction x. Optionally, the colors corresponding to the first sub-pixel 71, the second sub-pixel 72, and the third sub-pixel 73 are red, green, and blue, respectively.

In some embodiments, some of the pixels in the plurality of rows of pixels shown in FIG. 6 may be canceled, and a transparent material may be applied to the place where the pixels are initially arranged, such that the display panel is made of a transparent display panel. For example, the odd rows of pixels are cancelled and a transparent material is applied instead.

Embodiments of the present disclosure do not limit the quantity, color, and arrangement of sub-pixels contained in each pixel. In other examples, one pixel may include four sub-pixels, the colors corresponding to four sub-pixels may be red, blue, green and white, or red, blue, green and yellow, or the like, respectively.

In the embodiments of the present disclosure, at least some of sub-pixels include auxiliary electrode structures.

In the embodiments of the present disclosure, the plurality of auxiliary electrode structures 5 are arranged in an array on the drive backplane 1, the plurality of sub-pixels 70 are organized into a plurality of sub-pixel groups 700. Each of the sub-pixel groups 700 includes one sub-pixel includes the auxiliary electrode structure 5.

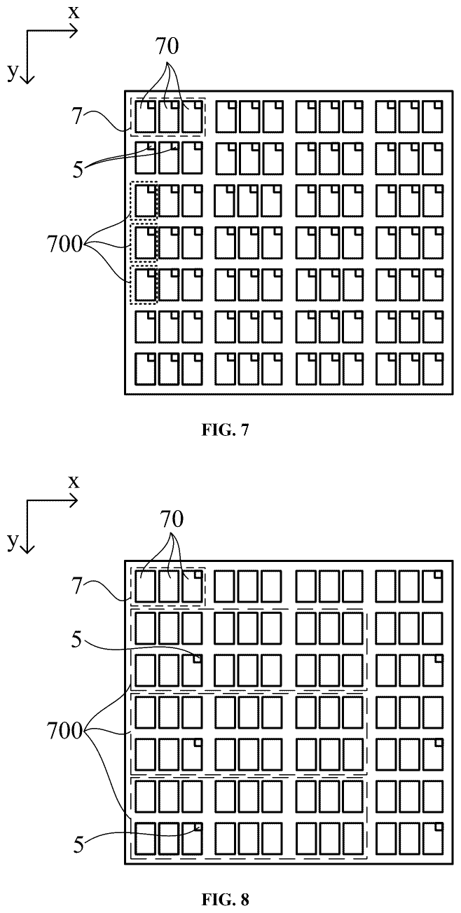

FIG. 7 is a schematic diagram of distribution of auxiliary electrode structures according to some embodiments of the present disclosure. In one possible embodiment, as shown in FIG. 7, each of the sub-pixel groups 700 includes one sub-pixel 70, that is, each of the sub-pixels includes one auxiliary electrode structure.

In some embodiments, each sub-pixel group 700 includes M rows and N columns of sub-pixels, wherein M and N are both positive integers. FIG. 8 is another schematic diagram of distribution of auxiliary electrode structures according to some embodiments of the present disclosure. For example, when M is 2 and N is 9, as shown in FIG. 8, one of 18 sub-pixels within each of the sub-pixel groups 700 includes one auxiliary electrode structure. In each of the sub-pixel groups 700, the relative positions of the sub-pixels 70 with the auxiliary electrode structures 5 in the sub-pixel group 700 are the same.

In some embodiments, the relative positions of the sub-pixels 70 with the auxiliary electrode structures 5 in the sub-pixel group 700 are different.

In the embodiments of the present disclosure, the light-emitting layer 3 includes a plurality of light-emitting structures, and the drive backplane 1 includes a substrate and a plurality of drive units 10 arranged in an array.

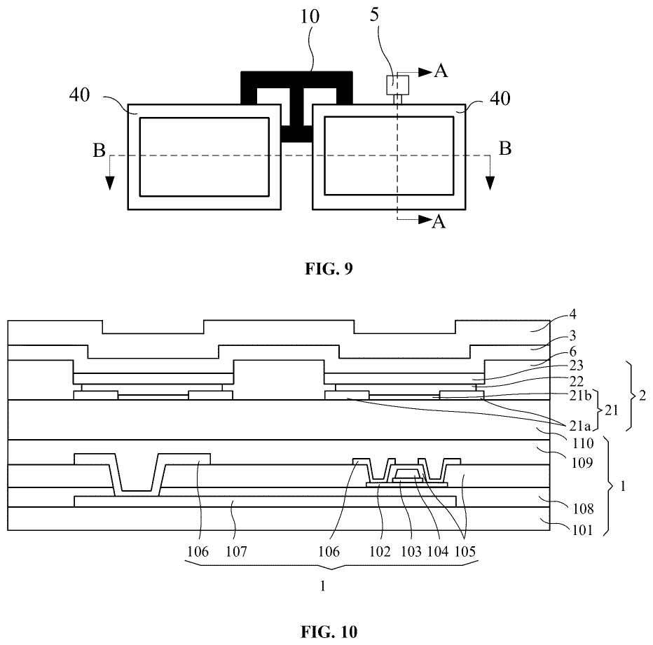

FIG. 9 is a schematic diagram of the top view structure of a sub-pixel including an auxiliary electrode structure according to some embodiments of the present disclosure, and FIG. 1 is a schematic cross-sectional structure diagram along line AA in FIG. 9. In FIG. 9, the first electrode structure and the light-emitting structure are not shown because they are partially obscured by the second electrode layer 4.

In conjunction with FIG. 1 and FIG. 9, one sub-pixel includes one auxiliary electrode structure 5, two first electrode structures, two light-emitting structures, a portion of the second electrode layer 40, and one drive unit 10. The drive unit 10 is electrically connected to two first electrode. Therefore, in a sub-pixel with an auxiliary electrode structure, the drive unit 10 is electrically connected to two first electrode structures, and the two first electrode structures are respectively connected to two light-emitting structure, such that the drive unit 10 can control two light-emitting structure. Where one of the light-emitting structure is incapable of emitting light normally, the drive unit may drive another light-emitting structure within the sub-pixel to emit light, thereby ensuring the normal display of the display panel as much as possible, and enhancing product reliability.

In some embodiments, the drive unit 10 may be electrically connected to one first electrode structure, and the first electrode structure is connected to one light-emitting structure, such that the drive unit 10 controls one light-emitting structure.

In some embodiments, the first sub-metal layer 52a is a monolayer structure, such as copper, silver, aluminum, molybdenum or niobium. The metal layer 22 of the first electrode structure and the second sub-metal layer 52b are both multi-layer stacked structures, such as a stacked structure formed by sequentially overlapping copper metal and copper alloy, wherein the copper alloy includes an alloy material formed by copper with one or more metals such as silver, aluminum, molybdenum, niobium or the like, for example, the copper layer and the molybdenum-niobium alloy layer that are alternately and sequentially stacked.

In some embodiments, the second conductive layer 23 of the first electrode structure and the second conductive layer 53 of the auxiliary electrode structure 5 are made of transparent conductive material, such as ITO, IZO (indium zinc oxide), or the like.

In some embodiments, the light-emitting layer 3 may include a hole transport layer (HTL), a hole injection layer (HIL), an electron transport layer (ETL), an electron injection layer (EIL), a hole block layer (HBL), an electron blocking layer (EBL), and a luminescent material layer. The electron injection layer, the electron transport layer, the hole block layer, the luminescent material layer, the hole transport layer, the hole injection layer, and the electron blocking layer are sequentially stacked.

In some embodiments, the second electrode layer 4 is made of a transparent conductive material, such as ITO, IZO, or the like.

The following is an exemplary description of the structure of the drive backplane 1. FIG. 10 is a schematic cross-sectional structure diagram of another display panel according to some embodiments of the present disclosure, and FIG. 10 is a schematic cross-sectional diagram along line BB in FIG. 9. Optionally, as shown in FIG. 10, the drive backplane 1 includes a substrate 101, a light shield layer 107, a buffer layer 108, an active layer 102, a gate insulation layer 103, a gate layer 104, an interlayer dielectric layer 105, a source-drain layer 106, a passivation layer 109, and an organic layer 110 that are sequentially stacked.

In the embodiments of the present disclosure, the substrate 101 may be any transparent substrate, such as a glass substrate, a quartz substrate, a plastic substrate, other transparent hard substrates, or other transparent flexible substrates, which may be monolayered or multilayered.

Taking a multilayered substrate as an example, the substrate includes a first polyimide (PI) layer, a first protective layer, a second PI layer, and a second protective layers that are sequentially stacked from bottom to top. The two protective layers are used to protect the PI layers and prevent damage to PI layer by subsequent processes. The second protective layer is also covered with a buffer layer that can block water oxygen and alkaline ions.

The substrate may also made of a silicon substrate, such as monocrystalline silicon or high-purity silicon. The silicon substrate integrates the various transistors included in the pixel drive circuit, for example, a source, a drain, and a gate of the transistor are formed in the silicon substrate by a doping process.

In some embodiments, the active layer 102 may be made of amorphous silicon, polycrystalline silicon, or a metal oxide semiconductor, or the like, such as low temperature poly-silicon (LTPS) and low temperature polycrystalline oxide (LTPO); the gate insulation layer 103 may be made of silicon oxide, silicon nitride or silicon nitride oxide, or the like.

In some embodiments, the gate layer 104 may be made of a monolayer metal film, such as a molybdenum layer, a copper layer, an aluminum layer, or a titanium layer; or may be a multi-layer metal film of a molybdenum layer, an aluminum layer, and a molybdenum layer that are sequentially stacked; or may be a multi-layer metal film of a titanium layer, an aluminum layer and a titanium layer that are sequentially stacked; and the interlayer dielectric layer 105 may be made of silicon oxide or silicon nitride.

In some embodiments, the source-drain layer 106 may be made of a monolayer metal film, such as an aluminum layer, a molybdenum layer, a copper layer, or a titanium layer; or may be a multi-layer metal film of a molybdenum layer, an aluminum layer, and molybdenum layer that are sequentially stacked; or may be a multi-layer metal film of a titanium layer, an aluminum layer, and a titanium layer that are sequentially stacked.

In some embodiments, the light shield layer 107 may be made of metal. In this case, the light shield layer 107 not only serves to shade active layer 102 from light, but also serves as a capacitive plate.

In some embodiments, the passivation layer 109 may be made of silicon oxide.

In some embodiments, the passivation layer 109 has a thickness of 3000 angstroms to 5000 angstroms.

In some embodiments, the organic layer 110 may be made of resin or the like.

In some embodiments, the display panel also includes a color film layer, the color film layer is disposed on a side, away from the drive backplane 1, of the second electrode layer 4 back. The color film layer includes a black matrix and a plurality of color resist blocks. The black matrix is disposed between any two adjacent color resist blocks. The plurality of color resist blocks are in one-to-one correspondence with a plurality of sub-pixels 70.

In some embodiments, the display panel further includes an encapsulation layer, wherein the encapsulation layer may be disposed between the second electrode layer and the color film layer. This configuration may be referred to as color on encapsulation (COE, integrating the color film or color filter in the encapsulation layer). The encapsulation layer may also be disposed on a side, away from the second electrode layer, of the color film layer.

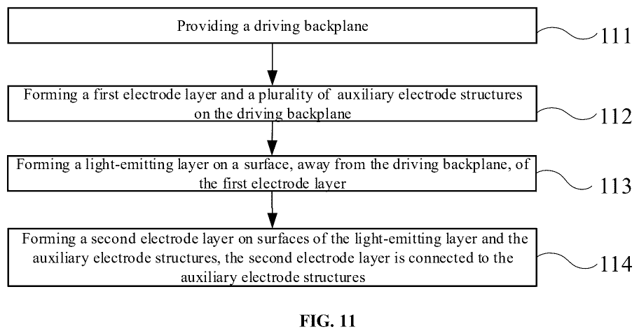

Embodiments of the present disclosure further provide a method for manufacturing a display panel. FIG. 11 is a flowchart of a method for manufacturing a display panel according to some embodiments of the present disclosure. The method is applicable to manufacturing any one of the display panels. As shown in FIG. 11, the method includes the following steps.

In process 111, a drive backplane is provided.

In process 112, a first electrode layer and a plurality of auxiliary electrode structures are formed on the drive backplane.

The first electrode layer includes a plurality of first electrode structures. An orthographic projection of each of the first electrode structures on the drive backplane is not overlapped with an orthographic projection of each of the auxiliary electrode structures on the drive backplane.

In process 113, a light-emitting layer is formed on a surface, away from the drive backplane, of the first electrode layer.

In process 114, a second electrode layer is formed on surfaces of the light-emitting layer and the auxiliary electrode structures, wherein the second electrode layer is connected to the auxiliary electrode structures.

Each of the first electrode structures includes a first transparent conductive layer, a metal layer, and a second transparent conductive layer that are sequentially stacked on the drive backplane in a direction away from the drive backplane. Each of the auxiliary electrode structures includes a first transparent conductive layer, a metal layer, and a second transparent conductive layer that are sequentially stacked on the drive backplane in the direction away from the drive backplane, wherein a thickness of the metal layer of the first electrode structure is less than a thickness of the metal layer of the auxiliary electrode structure.

In some embodiments, process 111 includes forming the drive backplane through the following steps.

In a first step, a substrate is provided.

In a second step, a shading metal layer is deposited on the substrate, a photoresist structure is obtained by processes such as photoresist coating, exposure, development, and the like, and a light shield layer is obtained by etching the shading metal layer using the photoresist structure as a mask.

In a third step, a buffer layer is deposited on the light shield layer.

In a fourth step, a semiconductor material layer, an insulating layer, and a gate metal layer are sequentially deposited on the buffer layer, a photoresist structure is obtained by processes such as photoresist coating, exposure, development, and the like, and a gate layer is obtained by etching a gate metal layer using the photoresist structure as a mask. The gate layer includes a plurality of block gates.

In a fifth step, a gate insulation layer is obtained from the insulating layer, and an active layer is obtained from the semiconductor material layer. Further, a portion of the active layer not covered by the gate layer is conductorized to ensure good ohmic contact between an active layer and a subsequently formed source-drain layer.

In a sixth step, an initial interlayer dielectric layer is deposited on the gate layer, and a plurality of vias exposing the light shield layer are formed by a series of processes such as photoresist coating, exposure, etching, stripping, and the like. Further a plurality of vias exposing the active layer are formed by a series of processes such as photoresist coating, exposure, etching, stripping and the like, such that an interlayer dielectric layer is obtained.

In a seventh step, a source-drain metal layer is deposited on the interlayer dielectric layer, and a source-drain layer is obtained by a series of processes such as photoresist coating, exposure, etching, stripping, and the like.

In an eighth step, an initial passivation layer is formed on the source-drain layer, and a plurality of via holes exposing the source-drain layer are formed by a series of processes such as photoresist coating, exposure, etching, stripping, and the like, such that a passivation layer is obtained.

In a ninth step, an initial organic layer is deposited on the passivation layer, and an organic layer is formed by photoresist coating and exposure.

In some embodiments, process 112 includes forming the first conductive layer of the first electrode structure and the first conductive layer of the auxiliary electrode structure through the following steps.

In a first step, a first conductive pattern layer formed on the drive backplane. The first conductive pattern layer includes a first sub-layer of the first electrode structure and a first sub-layer of the auxiliary electrode structure formed on the drive backplane, wherein the first sub-layer of the first electrode layer has a hollow structure.

In a second step, a second conductive pattern layer formed on the first conductive pattern layer to obtain a first conductive layer of a first electrode structure and a first conductive layer of an auxiliary electrode structure, and the second conductive pattern layer includes a second sub-layer of the first electrode structure and a second sub-layer of the auxiliary electrode structure. At least a portion of the second sub-layer of the first electrode layer is disposed in the hollow structure, and the second sub-layer of the auxiliary electrode structure is disposed on the first sub-layer of the auxiliary electrode structure.

In some embodiments, in the first step, a transparent conductive material layer is first formed, then a photoresist structure is obtained by processes of photoresist coating, exposure, development, and the like, the transparent conductive material layer is etched using the photoresist structure as a mask, and the transparent conductive material layer except for the regions of the first electrode structure and the auxiliary electrode structure is removed to obtain the first conductive pattern layer.

For details about formation of the second conductive pattern layer, reference may be made to the formation of the first conductive pattern layer.

In some embodiments, process 112 includes forming the metal layer of the first electrode structure and the metal layer of the auxiliary electrode structure through the following steps.

In a first step, a first metal pattern layer is formed, wherein the first metal pattern layer includes a first sub-metal layer of an auxiliary electrode structure.

In a second step, a second metal pattern layer is formed on the first metal pattern layer to obtain a metal layer of a first electrode structure and a metal layer of an auxiliary electrode structure, wherein the second metal pattern layer includes a metal layer of the first electrode structure and a second sub-metal layer of the auxiliary electrode structure.

In some embodiments, the first step includes: forming a metal layer; then obtaining a photoresist structure by processes of photoresist coating, exposure, development, and the like, etching the metal layer using the photoresist structure as a mask, and removing the metal layer auxiliary electrode structure area to forming the first metal pattern layer.

For details about formation of the second metal pattern layer, reference may be made to the formation of the first metal pattern layer.

In some embodiments, between process 112 and process 113, the method further includes forming a pixel define layer by deposition.

Embodiments of the present disclosure further provide a display device. The display device includes any one of the aforementioned display panels and a power supply circuit. The power supply circuit is configured to supply power to the display panel.

In some embodiments, the display device according to the embodiments of the present disclosure may be any product or component having the display function, such as a mobile phone, a tablet computer, a television, a display, a laptop computer, a digital photo frame, a navigation device, or the like.

The display device achieves the same effect as the display panel as described above, which is not repeated herein.

The beneficial effects from the technical solutions of the present disclosure achieve at least the following beneficial effect:

If the metal layer of the first electrode layer in the display panel is too thick, relatively large and impurity particles may be introduced when forming the metal layer of the first electrode layer, and these particles may pierce the light-emitting layer on the first electrode layer, causing a short circuit between the first electrode layer and the second electrode layer, and leading the dark-dot type defects. By thinning the thickness of the metal layer of the first electrode layer, the quantity and size of the particles introduced during the formation of the metal layer in the first electrode layer are reduced, thereby decreasing dark-dot type defects.

Described above are merely exemplary embodiments of the present disclosure, and are not intended to limit the present disclosure, and any modifications, equivalent substitutions, and improvements or the like made within the spirit and the principles of the present disclosure should be contained within the scope of protection of the present disclosure.

1. A display panel, comprising: a drive backplane, a first electrode layer, a light-emitting layer, a second electrode layer, and a plurality of auxiliary electrode structures; wherein
the first electrode layer and the auxiliary electrode structures are disposed on the drive backplane, and the first electrode layer comprises a plurality of first electrode structures, wherein an orthographic projection of each of the first electrode structures on the drive backplane is not overlapped with an orthographic projection of each of the auxiliary electrode structures on the drive backplane;
the light-emitting layer is disposed on a surface, away from the drive backplane, of the first electrode layer; and
the second electrode layer covers the light-emitting layer and the auxiliary electrode structures, and the second electrode layer is connected to the auxiliary electrode structures;
wherein each of the first electrode structures comprises a first conductive layer, a metal layer, and a second conductive layer that are sequentially stacked on the drive backplane in a direction away from the drive backplane, and each of the auxiliary electrode structures comprises a first conductive layer, a metal layer, and a second conductive layer that are sequentially stacked on the drive backplane in the direction away from the drive backplane, wherein a thickness of the metal layer of the first electrode structure is less than a thickness of the metal layer of the auxiliary electrode structure.

2. The display panel according to claim 1, wherein the first conductive layer and the second conductive layer of the first electrode structure, and the first conductive layer and the second conductive layer of the auxiliary electrode structure are all made of a transparent material.

3. The display panel according to claim 2, wherein the metal layer of the auxiliary electrode structure comprises a first sub-metal layer and a second sub-metal layer that are sequentially stacked in a direction away from the drive backplane, wherein a thickness of the second sub-metal layer is equal to the thickness of the metal layer of the first electrode layer, and the second sub-metal layer and the metal layer of the first electrode structure are made of a same material.

4. The display panel according to claim 3, wherein the thickness of the metal layer of the first electrode structure is greater than or equal to 400 angstroms and less than or equal to 1500 angstroms.

5. The display panel according to claim 3, wherein the first sub-metal layer is a monolayer structure.

6. The display panel according to claim 3, wherein the metal layer of the first electrode structure and the second sub-metal layer are both multi-layer stacked structures.

7. The display panel according to claim 1, wherein the first transparent conductive layer of the first electrode structure comprises a first sub-layer and a second sub-layer that are sequentially stacked in the direction away from the drive backplane, wherein the first sub-layer is a crystallized indium tin oxide layer, and the second sub-layer is a buffer indium tin oxide layer.

8. The display panel according to claim 7, wherein a hollow structure is arranged at a middle portion of the first sub-layer of the first electrode structure, wherein at least a portion of the second sub-layer of the first electrode structure is disposed within the hollow structure.

9. The display panel according to claim 8, wherein the thickness of the first sub-layer of the first electrode structure is greater than or equal to the thickness of the second sub-layer of the first electrode structure, and the metal layer of the first electrode structure covers the hollow structure and is connected to at least a portion of the surface, away from the drive backplane, of the first sub-layer of the first electrode structure.

10. The display panel according to claim 1, wherein the first transparent conductive layer of the auxiliary electrode structure comprises a first sub-layer and a second sub-layer that are sequentially stacked in the direction away from the drive backplane, wherein the first sub-layer of the auxiliary electrode structure and the first sub-layer of the first electrode structure are disposed on a same layer and are made of a same material, and the second sub-layer of the auxiliary electrode structure and the second sub-layer of the first electrode structure are disposed on a same layer and are made of a same material.

11. The display panel according to claim 1, further comprising: a plurality of sub-pixels, wherein the sub-pixels are organized into a plurality of sub-pixel groups, and at least one sub-pixel of each of the sub-pixel groups comprises the auxiliary electrode structure;
wherein each of the sub-pixel groups comprises one sub-pixel or comprises M rows and N columns of sub-pixels, wherein M and N are both positive integers.

12. The display panel according to claim 11, wherein
the light-emitting layer comprises a plurality of light-emitting structures, and the drive backplane comprises a plurality of drive units; and
the first sub-pixel of the sub-pixels comprises one auxiliary electrode structure, two first electrode structures, two light-emitting structures, a portion of a second electrode layer, and a first drive unit, wherein the first drive unit is one of the drive units;
wherein in the first sub-pixel, the first drive unit is electrically connected to the two first electrode structures.

13. The display panel according to claim 1, wherein in the auxiliary electrode structures, along a direction parallel to the drive backplane, an edge, close to any of the first electrode structures, of the second conductive layer protrudes from an edge, close to the same first electrode structure, of the metal layer, such that a protrusion structure is formed, wherein the protrusion structure interrupts the second electrode layer, and the interrupted portion of the second electrode layer is connected to the metal layer of the auxiliary electrode structures.

14. A method for manufacturing a display panel, comprising:
providing a drive backplane;
forming a first electrode layer and a plurality of auxiliary electrode structures on the drive backplane, wherein the first electrode layer comprises a plurality of first electrode structures, an orthographic projection of each of the first electrode structures on the drive backplane is not overlapped with an orthographic projection of each of the auxiliary electrode structures on the drive backplane;
forming a light-emitting layer on a surface, away from the drive backplane, of the first electrode layer; and
forming a second electrode layer on surfaces of the light-emitting layer and the auxiliary electrode structures, wherein the second electrode layer is connected to the auxiliary electrode structures;
wherein each of the first electrode structures comprises a first transparent conductive layer, a metal layer, and a second transparent conductive layer that are sequentially stacked on the drive backplane in a direction away from the drive backplane; and each of the auxiliary electrode structures comprises a first transparent conductive layer, a metal layer, and a second transparent conductive layer that are sequentially stacked on the drive backplane in the direction away from the drive backplane, wherein a thickness of the metal layer of the first electrode structure is less than a thickness of the metal layer of the auxiliary electrode structure.

15. A display device, comprising: a display panel and a power supply circuit; wherein
the power supply circuit is configured to supply power to the display panel;
the display panel comprises a drive backplane, a first electrode layer, a light-emitting layer, a second electrode layer, and a plurality of auxiliary electrode structures;
wherein the first electrode layer and the auxiliary electrode structures are disposed on the drive backplane, and the first electrode layer comprises a plurality of first electrode structures, wherein an orthographic projection of each of the first electrode structures on the drive backplane is not overlapped with an orthographic projection of each of the auxiliary electrode structures on the drive backplane;
the light-emitting layer is disposed on a surface, away from the drive backplane, of the first electrode layer; and
the second electrode layer covers the light-emitting layer and the auxiliary electrode structures, and the second electrode layer is connected to the auxiliary electrode structures;
wherein each of the first electrode structures comprises a first conductive layer, a metal layer, and a second conductive layer that are sequentially stacked on the drive backplane in a direction away from the drive backplane, and each of the auxiliary electrode structures comprises a first conductive layer, a metal layer, and a second conductive layer that are sequentially stacked on the drive backplane in the direction away from the drive backplane, wherein a thickness of the metal layer of the first electrode structure is less than a thickness of the metal layer of the auxiliary electrode structure.

16. The display device according to claim 15, wherein the first conductive layer and the second conductive layer of the first electrode structure, and the first conductive layer and the second conductive layer of the auxiliary electrode structure are all made of a transparent material.

17. The display device according to claim 15, wherein the first conductive layer of the first electrode structure comprises a first sub-layer and a second sub-layer that are sequentially stacked in the direction away from the drive backplane, wherein the first sub-layer is a crystallized indium tin oxide layer, and the second sub-layer is a buffer indium tin oxide layer.

18. The display device according to claim 15, wherein the first conductive layer of the auxiliary electrode structure comprises a first sub-layer and a second sub-layer that are sequentially stacked in the direction away from the drive backplane, wherein the first sub-layer of the auxiliary electrode structure and the first sub-layer of the first electrode structure are disposed on a same layer and are made of a same material, and the second sub-layer of the auxiliary electrode structure and the second sub-layer of the first electrode structure are disposed on a same layer and are made of a same material.

19. The display device according to claim 15, wherein the display panel further comprises: a plurality of sub-pixels, wherein the sub-pixels are organized into a plurality of sub-pixel groups, and at least one sub-pixel of each of the sub-pixel groups comprises the auxiliary electrode structure;
wherein each of the sub-pixel groups comprises one sub-pixel or comprises M rows and N columns of sub-pixels, wherein M and N are both positive integers.

20. The display device according to claim 15, wherein in the auxiliary electrode structures, along a direction parallel to the drive backplane, an edge, close to any of the first electrode structures, of the second conductive layer protrudes from an edge, close to the same first electrode structure, of the metal layer, such that a protrusion structure is formed, wherein the protrusion structure interrupts the second electrode layer, and the interrupted portion of the second electrode layer is connected to the metal layer of the auxiliary electrode structures.
